(19) United States
(12) Patent Application Publication
(10) Pub. No.: US 2006/0054985 A1
(43) Pub. Date: Mar. 16, 2006

(54) Artificial ferromagnetism in semiconducting arrays

(76) Inventor: Daniel C. Mattis, Salt Lake City, UT (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/122,948

(22) Filed: May 5, 2005

Related U.S. Application Data
(60) Provisional application No. 60/568,381, filed on May 5, 2004.

(51) Int. Cl. H01L 27/14

(52) U.S. Cl. 257/428

(57) ABSTRACT

Nanostructures are provided having electronic properties suitable for artificial ferromagnetism or anti-ferromagnetism in semiconducting arrays. An artificial ferromagnet device comprises an insulator substrate, and a semiconductor material over the insulator substrate. The semiconductor material has a bipartite architecture comprising interconnected, nonmagnetic nanodots organized into a plurality of cells in a trellis structure in which there is one electron per nanodot. Similarly, a nano-logical memory element comprises an insulator substrate, and a semiconductor material over the insulator substrate. The semiconductor material has a bipartite architecture comprising interconnected, nonmagnetic nanodots with a given electron concentration. A method is also provided for insulator-to-metallic transition that allows for signal and power amplification when a semiconductor array is imbedded in MOSFET geometry.

### RELATED APPLICATIONS

This application claims the benefit of U.S. Provisional Patent Application No. 60/568,381 filed on May 5, 2004, entitled ARTIFICIAL FERROMAGNETISM IN SEMICONDUCTING ARRAYS, which is incorporated herein by reference.

### BACKGROUND OF THE INVENTION

1. Field of the Invention

The present invention relates to techniques for particle localization by geometrical nanostructures. More specifically, the invention relates to nanostructures having electronic properties suitable to provide artificial ferromagnetism or anti-ferromagnetism in semiconducting arrays.

2. Relevant Technology

Nanotechnology is a rapidly evolving field. The race is on to develop self-organizing structures that can be used as active circuit elements. For example, U.S. Pat. No. 6,459,095 B1 discloses a process that traps electrically switchable molecules between crossed wires only a few atoms wide, allowing for the creation of a manufacturable molecular electronic technology. There is also currently a great deal of interest in quantum dots (nanodots), which are three-dimensional heterostructures measuring about 1 nm to about 100 nm in each direction, in which electrons, holes, and/or excitons may be confined.

Superconductivity, traditionally a low temperature phenomenon (T<25 K) that is found in some “bad” metals (Pb, Sn, Hg, Nb, etc.) and their alloys, was discovered a century ago. A fundamental theory was lacking until 1957 when Bardeen (also co-inventor of the transistor), and his students Cooper and Schrieffer developed the Bardeen-Cooper-Schrieffer (BCS) electron-pairing theory that is at the heart of our present-day understanding. In 1986, Berdnoz and Müller found the first “high-temperature superconductor” (HTS), capable of superconductivity at temperatures some 50% higher than the previous best and believed by many researchers to be ultimately capable of exceeding room temperature (20° C.) in future developments. The pairing is the same but the mechanism that causes pairing appears to be novel. Unlike “low” temperature superconductors, the HTS have been found to-date only in the layered CuO₂ planes that can occur in crystals of the perovskite type. When each CuO₂ unit contains precisely 5 active electrons, the collective behavior is that of a single spin ½. Each CuO₂ plane resembles a spin ½ Heisenberg antiferromagnet, weakly coupled from plane to plane. Even such weak coupling allows for a Néel temperature of up to 1000 K, indicating that the in-plane coupling parameter J is substantial. When electrons are taken away, say a fraction f is removed (f is typically in the range of 5%-25%), a fraction f of the CuO₂ units will acquire spin 0 and a charge +e relative to the other units. This missing electron is called a “hole”. The presence of holes allows metallic conductivity and superconductivity in CuO₂.

Experimentally the BCS energy gap is not isotropic across the Fermi surface in HTS as it is in the low-temperature superconductors, but has nodes corresponding to so-called “d-waves.” The study of many-body systems (e.g., Hubbard model, t-J models) has indicated that holes promote electronic conductivity and superconductivity, that HTS is mediated by the same antiferromagnetic forces measured by J as the antiferromagnet, and that the gap should have d-wave symmetry. However, there is complete disagreement and confusion in the physics community regarding the precise mechanism and the exact model parameters that apply.

Computer simulations of the Hubbard and t-J models have failed to be definitive, owing to the difficulty, of solving the many-fermion problem on a sufficiently large lattice—even approximately.

Memory elements are traditionally dichotomic—such as spin “up” or “down.” In giant magnetoresistance (GMR,) a current is modulated by whether two magnetic fields applied to two nearby conducting elements are parallel or antiparallel. But this set-up is difficult to miniaturize, as the power expended in electrical currents can quickly exceed the ability of the material to dissipate and causes meltdown when circuit elements are densely packed.

Microdots have been made out of specially designed semiconductors embedded in a host material. They trap from 1 to 100 electrons, or valence band holes, or combinations of both called “excitons.”

Field effect transistors (FET) are commonly used for weak-signal amplification, d-c switching or signal generation. In a MOSFET (metal-oxide semiconductor FET), the conductivity of a channel is affected by transverse voltage applied at a gate. This metallic gate, acting across a metal-oxide insulating layer, capacitatively charges the channel, thus affecting its conductivity. The gate in the MOSFET has a high input impedance, therefore low input power. The modulation of the channel width by the gate voltage can be large, therefore there is a large output current and power gain inherent in such devices. If the oxide layer is very thin the electrical fields are high and the density of carriers could be changed capacitatively, further optimizing the amplification. But thin dielectrics are fragile, breaking down at or less than 10⁶ v/cm. This limits the ability to modulate charge density by capacitative structures in conventional MOSFETs.

### SUMMARY OF THE INVENTION

The present invention is directed to nanostructures having electronic properties suitable to provide artificial ferromagnetism or anti-ferromagnetism in semiconducting arrays. In this unique approach to nanotechnology, electrons are trapped in variously shaped and connected quantum states within intrinsic semiconductors. The shape and the connectivity (i.e., the “architecture”) determine where the electrons are confined and govern their mutual interactions.

In one aspect of the invention, an artificial ferromagnet device comprises an insulator substrate, and a semiconductor material over the insulator substrate. The semiconductor material has a bipartite architecture comprising interconnected, nonmagnetic nanodots organized into a plurality of cells in a trellis structure in which there is one electron per nanodot.

In another aspect of the invention, a nano-logical memory element comprises an insulator substrate, and a semiconductor material over the insulator substrate. The semiconductor material has a bipartite architecture comprising interconnected, nonmagnetic A and B nanodots with a given electron concentration v=1. The arrayed nanodots have a permanent magnetic moment M=m₀|N_{A}−N_{B}| where m₀ is the Bohr magneton, with N_{A} and N_{B} being the number of A and B nanodots, respectively.

In a further aspect of the invention, a method is provided for insulator-to-metallic transition that allows for signal and power amplification when a semiconductor array is imbedded in MOSFET geometry. The method comprises providing a semiconductor array having a bipartite architecture comprising interconnected, nonmagnetic A and B nanodots organized into a plurality of cells in which an insulator phase exists at or near electron concentrations per nanodot of v=1. A phase transition to a metallic phase occurs at or below an average electron concentration v_{c}, where v_{c} is less than 1 or when v is at or near v_{c′}, where v_{c′} is greater than 1. A value of v is biased near v_{c} or v_{c′} where the conductivity of the semiconductor material is most sensitive to small changes in electron concentration.

A three-dimensional architecture of intersecting channels, such that one electron can be trapped in each intersection and the space lattice can be decomposed into two interpenetrating lattices, one of which has vastly more electrons than the other, also comprises a macroscopic ferromagnet within the scope of this invention.

These and other features of the present invention will become more fully apparent from the following description and appended claims, or may be learned by the practice of the invention as set forth hereinafter.

### BRIEF DESCRIPTION OF THE DRAWINGS

To further illustrate the above and other features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a schematic depiction of one embodiment of a ferromagnetic array in a square lattice molecular grid showing the layout of intrinsic semiconductor spheres with interconnecting cylinders;

FIG. 2 is a schematic depiction of the ferromagnetic array of FIG. 1, showing the relative spins and charges when the electron number is slightly less than 1 per bubble on average;

FIG. 3 is a schematic depiction of another embodiment of the invention having branching structures, showing the relative spin orientation of two electrons bound at the neighboring branch junctions;

FIG. 4 is a schematic depiction of a further embodiment of the invention having an elementary branching network, with a bipartite cluster of sites randomly connected to one another; and

FIG. 5 is a graph showing the “effective” ferromagnetic coupling constant J*vs. kT, both in units of J.

### DETAILED DESCRIPTION OF THE INVENTION

The present invention is directed to a unique approach to nanotechnology in which electrons are trapped in variously shaped and connected quantum states within intrinsic semiconductors ranging from about 10 nm to about 100 nm in dimensions. The shape and the connectivity (i.e., the “architecture”) determine where the electrons are confined and govern their mutual interactions. Depending on such factors as the architecture, the number of injected electrons in each unit cell, and the temperature, the following features have been discovered. These include the creation of arbitrarily large two-dimensional synthetic magnetic molecules, without the use of any magnetic ions; the creation of two-dimensional metals or possibly superconductors, without the use of any ions other than the intrinsic semiconducting material itself; and the switching from one such thermodynamic phase to another merely by varying an external voltage “control.” This suggests high signal amplification and the design of a powerful new type of transistor. The figures described hereafter illustrate one proposed geometry of the semiconducting layer and its magnetization, and the possibility of charge transport by “holes.”

One of the goals of “spintronics” has been the production and manipulation of spin-polarized electrons in microelectronic circuitry. It has been found in the present invention that magnetically polarized arrays of arbitrary size can be constructed out of nonmagnetic semiconducting material, such as intrinsic silicon laid over an insulator substrate, into which electrons can be injected by standard capacitative mechanisms.

The present design implements, in a two-dimensional trellis structure, a mathematical theorem by Lieb that relates the spontaneous spin-magnetism of a network to its connectivity and its geometry. The theorem proved by Elliott Lieb, Phys. Rev. Lett. 62, 1201 (1989), on which the present model is based, applies—strictly speaking—only to a mathematical model called the Hubbard model. It generalizes earlier work by E. Lieb and D. Mattis, J. Math. Phys. 3, 749 (1961), concerning the Heisenberg model in bipartite lattices with antiferromagnetic exchange interactions. The “bubbles” and “channels” of the present invention, discussed hereafter, have been designed to mimic the parameters of the Hubbard model insofar as this is possible. The present design is based on a phenomenon of wave mechanics that has only been understood in recent years: the formation of localized states at singularities in “electron waveguides.” Interesting results are also found in one-dimensional arrays, and even three-dimensional arrays, although more difficult to fabricate, are conceptually similar.

Lieb's theorem applies to interacting electrons on any half-filled bipartite networks in the Hubbard model of interacting electrons, regardless of dimensionality, geometry, or order. The term “bipartite” implies that an electron on an A nanodot site can only “hop” (i.e., be transferred,) to a nearby B nanodot site, and vice-versa, with A to A or B to B hops being prohibited. It can be proved that the ground-state of any such system belongs to total spin moment Sₜₒₜ=(½)|N_{A}−N_{B}| (in units of h-bar). N_{A} and N_{B} are respectively the number of A and B sites, not necessarily equal and not necessarily ordered and M, the total magnetization, is proportional to Sₜₒₜ.

The theory of the present invention is described in part in a copending patent application U.S. Ser. No. 10/737,178, filed on Dec. 16, 2003, the disclosure of which is incorporated herein by reference.

In order to illustrate the invention, a nano-array is specified that, by virtue of Lieb's theorem, must exhibit spontaneous ferromagnetism (also called ferrimagnetism). Other designs that satisfy the conditions that Sₜₒₜ=(½)|N_{A}−N_{B}|≠0 are similar, mutates mutandis. Although the following discussion relates to a two-dimensional array, it should be understood that the present invention can be a one-dimensional array or a three-dimensional array.

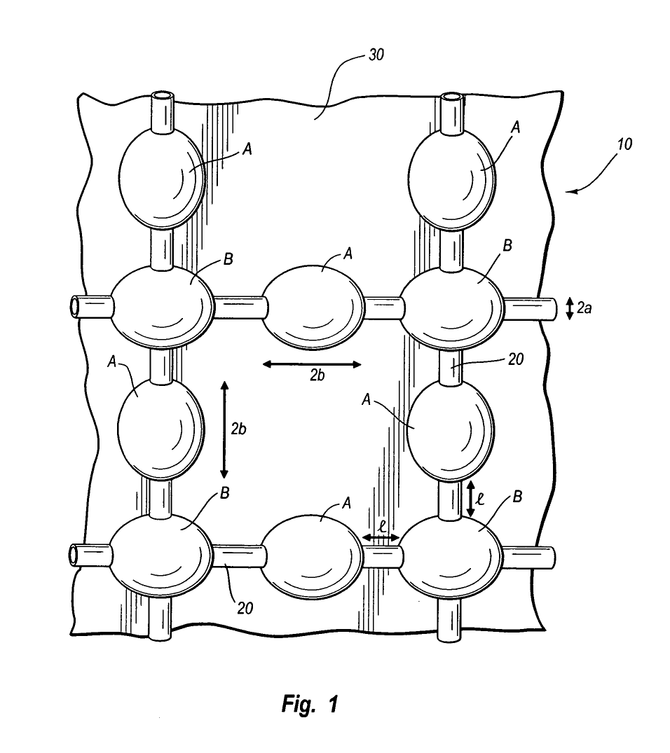

In one embodiment, the invention physically includes identical, interconnected, nonmagnetic nanodots made of an intrinsic semiconductor material, such as silicon, indium antimonide, gallium arsenide, indium phosphide, germanium, and the like, organized into N cells in a two-dimensional trellis structure in which N_{A}=2N_{B}=2N. FIG. 1 illustrates the layout of intrinsic silicon spheres (“bubbles” ) and silicon cylinders (“channels”) that connect the spheres in one embodiment of a synthetic ferromagnetic array 10. The array 10 is depicted with an architecture of a “decorated” square lattice of planar CuO₂, with Cu and O ions replaced by a set of identical spherical objects (bubbles) A and B (to distinguish them from the usual quantum dots,) of radius O (about 10 nm). The bubbles are connected by narrower cylinders 20 (channels) made of the same material as the bubbles. The radii, b, of the bubbles and the radii, a, and lengths l of the channels, as illustrated in FIG. 1, are picked to favor electron occupancy of bubbles over channels. The array 10 is formed over an insulator substrate 30, which can be various materials such as sapphire, quartz, and the like. The channels can be formed of nanotubes, such as carbon nanotubes, and can have a radius of about 1 nm to about 100 nm. The nanodots can have a radius of about 1 nm to about 100 nm, but are generally wider than the channels.

In one example of array 10, the spherical radius b=1.5a, and an optimal cylinder length l=1.683a. The magnitude of a (cylinder radius) is arbitrary—until Coulomb forces and effective exchange interactions are taken into account and optimized. Then it is determined to be in a range of less than about 100 nm, depending sensitively on the semiconductor's dielectric constant and the effective mass of the carriers.

The array 10 shown in FIG. 1 can be fabricated by nanolithagraphy followed by selective etching and vapor deposition. Instead of using ion implantation or chemical doping to introduce electrons into the neutral semiconductor material, subsequent injection by tunneling can be employed, using a standard capacitative method such as that which forms conventional MOSFET devices. The required density of electrons in the present design is quite low and therefore achievable (i.e., on the order of 10¹²/cm²). To the extent that this density of electrons can be modulated by an external electromagnetic field (EMF), the geometry of the array of the invention becomes capable of high signal amplification at low thermal dissipation, both valuable design considerations.

An alternative fabrication approach for the invention generalizes the “virtual” channels that are created in a semiconductor by electrostatic induction using shaped metallic electrodes, as described by Berggren and Pepper, New Directions with Fewer Dimensions, Physics World, October 2002, pp. 1-6, the disclosure of which is incorporated herein by reference. Although more difficult to analyze than the present model and less flexible in its device applications, a shaped-metal architecture might prove easier to fabricate than a shaped-semiconductor architecture that serves the same purpose.

The design of the present invention can also be used to make magnetic memory elements, as well as in other applications. As shown in FIG. 1, each bubble is connected by channels to either two or four nearest-neighbor spheres. The spheres that “decorate” the square lattice are assigned to the A sublattice while the corner spheres constitute the B sublattice, an ordinary sq lattice. In an infinite array, the unit cell can be chosen to include one B and two nearest-neighbors A (e.g., one immediately above it and the other immediately to its right.) Lieb's theorem specifies that for exactly 3N electrons (one per bubble and none in the channels), the ground state spin per unit cell is ½ (in units of h-bar) so that for N cells there can be a magnetic memory element corresponding to a spin N/2. Lowering the number of electrons to somewhat fewer than 3 per cell or raising the number of electrons to somewhat more than 3 per cell will lead to metallic phases.

The present disclosure has assumed use of a semiconductor that is induced to be n-type by injection of electrons. But by symmetry, the word “electron” also can be replaced by “hole,” the charge carrier in the valence band of semiconductors, if the semiconductor is induced to be p-type by injection of holes.

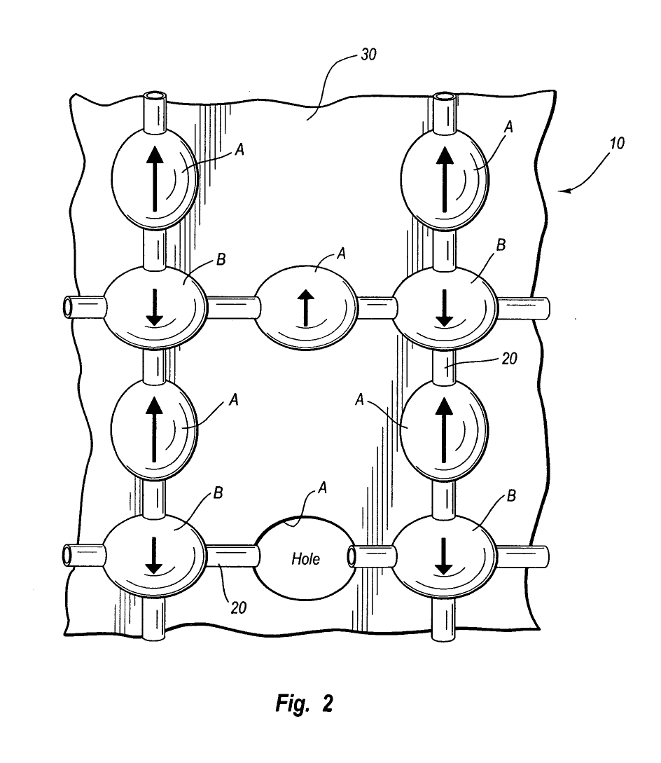

FIG. 2 depicts the ferromagnetic array 10 of FIG. 1, showing the relative spins and charges when the electron number is slightly less than 1 per bubble on average. A “hole” (a missing majority electron of spin ½) shown in FIG. 2 on an A site, is unstable on B sites but can tunnel (after a 15-step “ring exchange” that leaves no “string” behind) onto a diagonally neighboring A site, thereby exhibiting incipient metallic conduction along the (1,1) axes (see S. A. Trugman, Phys. Rev. B37, 1597 (1988), describing hole motion in a sq lattice). A nearest-neighbor exchange mechanism suggests looking for Cooper-pairing and incipient superconductivity when the number of electrons per cell is sufficiently reduced below 3 or raised sufficiently above it for the ferromagnetic order to be squelched.

Specific solutions, of the Schrodinger equation allow for the optimization of values for the parameters a, l, and b such that electrons are localized principally in the bubbles and not in the channels that connect them. The idealized ferromagnet of this design is an electrical insulator, because the on-site Coulomb interaction is sufficiently strong to discourage charge fluctuations (as in the “Coulomb blockade” in the standard example of a single microdot). Alterations in the architecture—specifically in the connectivity—can produce an ordered antiferromagnet (Sₜₒₜ=0) instead. Reduction in electron concentration to fewer than 1 electron per bubble should cause metallic charge transport to occur.

The present invention also includes artificial ferromagnets constructed out of a semiconductor material in the form of any “bipartite” architecture in which there is injected, or in which there exists ab initio, 1 electron per “bubble.” The number of A bubbles must differ from the number of B bubbles, e.g., as described previously.

In addition, the present invention includes a method for insulator-to-metallic transition that allows for signal and power amplification when the semiconductor array is imbedded in MOSFET geometry. The insulator phase exists at or near electron concentrations per nanodot of v=1. The phase transition to a metallic phase occurs at or below an average electron concentration v_{c} (where v_{c}<1) or for more than 1 electron per bubble,(i.e., when v is at or near v_{c′}, where v_{c′}>1). By biasing the value of v near v_{c} or v_{c′}, it is possible to increase the sensitivity of the conductivity of the semiconductor material by a large factor through small external changes in bias voltage that changes the actual value of v.

When the present invention is employed in a memory element, small arrays with a given v=1 will have a permanent magnetic moment M=m₀|N_{A}−N_{B}| until the value of v is changed sufficiently (“erasing” by raising or lowering v) that Sₜₒₜₐₗ→0. Thus, the magnitude of the magnetic moment can be used as a memory element, instead of or in addition to its orientation.

In alternative embodiments of the invention, the nanodots of the arrays can comprise branchings, bends, or bulges in channels such as hollow nanotubes. It is believed that the ferromagnetic electrons reside within the hollow nanotubes and are not part of the stable network of bonding molecules that constitute the surfaces of the nanotubes. The branching is, however, essential to understanding the creation of electronic bound states. It is also crucial to understanding the inequality N_{A}≠N_{B}.

In general, wherever a nanotube branches out, such as a carbon nanotube, an electron trap is created inside the junction. Electrons occupying neighboring junctions align their spins antiparallel. If there are more sites on sublattice A than on the interpenetrating sublattice B, the net result is M=m₀|N_{A}−N_{B}|.

Ferromagnetism is produced in these structures because of: (1) the presence of channels that allow electrons to move; (2) the formation of bound states at singularities in the channels (e.g., at a branching of one channel into two, or at a bulge or bend in any given channel); (3) the antiferromagnetic correlations of two electrons trapped on nearby bound states; and (4) an unequal number of sites on two interpenetrating sublattices that contain electrons of spin up and down respectively.

A. Formation of Bound, Localized States and Their Interactions

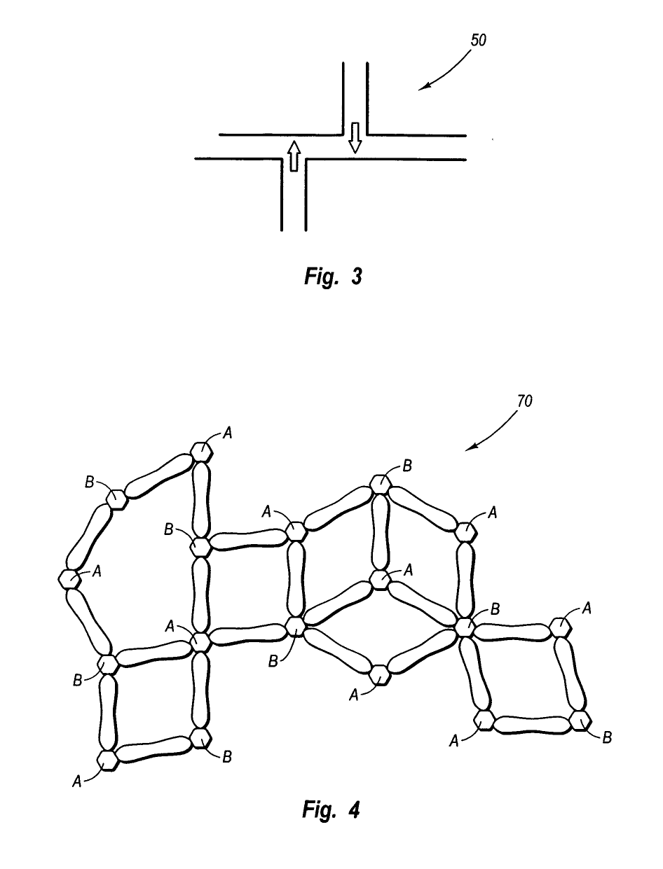

Bulges, bends or branching in a hollow tube, in which mobile electrons are confined (subject to boundary conditions Φ=0 on the surfaces), naturally cause the appearance of a bound state that is localized at the bulge, bend or branch. For example, a pair of branching “tee” structures 50 is illustrated in FIG. 3, showing the relative spin orientation of two electrons bound at the neighboring branch junctions (“tees”). Assuming the minimum energy of an electron confined in the channels is ε₀=η²π²/2ma² (a=diameter), we find the energy of a bound state at the bifurcation ε_{b} to be lower in the amount ε₀−ε_{b}=ε₀×0.35356, and the singlet-triplet splitting J of two bound electrons at a distance 2a apart to be approximately J=170 kB (in temperature units). For example, when a≈6 nm for the diameter of the nanotube, the allowed energies form a continuum ε₀+η²q²/2m above the minimum energy, where ηq is the longitudinal momentum along each channel. Additionally, a unique localized state is formed at each “tee” structure. The energy is calculated using WKB. A bound state is substantially lower than the minimum channel energy, i.e., ε_{b}=β₀×0.6464 for this geometry.

The triplet-singlet splitting of 2 electrons trapped on two neighboring “tees” a distance 2a (12 nm) apart can be calculated as follows: the energy of the antisymmetric, antibonding orbital is ε₀×0.6648 while that of the symmetric orbital is ε₀×0.6307, yielding an effective “hopping matrix element” t=ε₀×0.017. The “Hubbard U” is estimated at e²/2a=ε₀/π², therefore J=4t²/U=ε₀×0.0114. With ε₀=15000 k_{B} in ⁰K, the other energies correspond roughly to U=1500 k_{B}, t=250 k_{B} and J=170 k_{B}; all are reasonable “ballpark” figures for this physical system, the dynamics of which can be described by an antiferromagnetic Hamiltonian, H_{1,2}=JS₁−S₂.

As can be seen, whenever two nearest-neighbor trapped electrons interact, their joint singlet state is always favored over the triplet. With splitting defined as J, a standard estimate is J=4t²/U, where t is the “hopping” matrix element defining the overlap of the single particle wavefunctions at the two sites and U is the Coulomb repulsion when both occupy the same site. Thus, perhaps paradoxically, ferromagnetism is triggered by antiferromagnetic bonds J. FIG. 4 shows a two-dimensional version of an elementary branching network 70 for which this is expected: a sort of Cayley tree. It is clear that, absent any “fine tuning,” the numbers N_{A}≈N_{B} on such a lattice. In the branching network 70, ten sites labeled A connect with eight sites labeled B only, and vice-versa; thus, the net spin in the ground state is S₀η/2π. Ten sites have a coordination number z=2, five sites have z=3, two sites have z=4, and one site has z=5. On a pure Cayley tree of branching number 2, half the sites are at the surface, and the number of A sites is precisely double that of the B sites. Complex fractal structures can be formed that constitute a similar three-dimensional lattice, such as from carbon foam.

B. Renormalized Coupling Constants

Given the antiferromagnetic A,B couplings J, one is able to calculate the effective ferromagnetic coupling constant J* between next-nearest neighbor spins as follows. Without loss of generality, we suppose the A's to be the majority sites, then eliminate the B's that separate the closest pairs of A's. Ising-like bonds provide a simple example; Heisenberg bonds are more realistic but also more complicated to evaluate, therefore for them we just quote the final result.

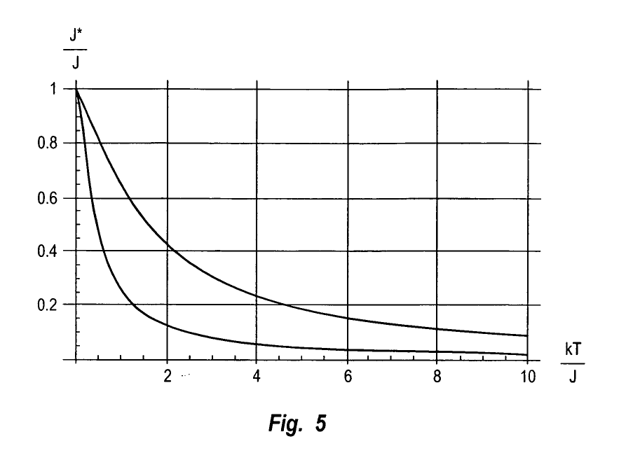

FIG. 5 is a graph showing the “effective” ferromagnetic coupling constant J* vs. kT, both in units of J. The upper curve in the graph is for the Ising model, Eq. (2), and the lower curve is for the Heisenberg model, Eq. (3), which are discussed hereafter.

In the Ising version, we evaluate <exp−JS_{B}(S_{A1}+S_{A2})/kT>, averaging over the values of the intervening B spin S_{B}=±1. We know this must result in a form Cexp(K* S_{A1}S_{A2}). The parameters C and K* are extracted as follows:

$$\begin{matrix}< {ⅇ}^{- {JS}_{B} ( {S}_{A1} + {S}_{A2} ) / kT} {>}_{B} = {cosh}^{2} ( J / kT ) + {S}_{A1} {S}_{A2} {sinh}^{2} ( J / kT ) \\ = ( \sqrt{cosh 2 J / kT} ) {ⅇ}^{K * {S}_{A1} {S}_{A2}}\end{matrix} \qquad ( 1 )$$

where tan hK*=tan h²K, and K*=J*/kT and K=J/kT. The ratio J*/J is a function of T:

$$\frac{{J}^{*}}{J} = \frac{log ( cosh 2 K )}{2 K} ( Ising model . ) \qquad ( 2 )$$

The ratio J*/J decreases from a maximum 1 (at low T) to 0 (at high T) as shown in the graph of FIG. 5. The calculation for the Heisenberg model (spins ½) is more realistic but somewhat more involved. After setting η=1, each spin is written in the form S=(σₓ, σ_{y}, σ_{z})/2, where the σ's are the three Pauli matrices. The average <exp−JS_{B}(S_{A1}+S_{A2})/kT>_{B} over the states of B must be reëxpressed in the form C(K)e^{K*S}^{_{A1}}^{S}^{_{A2}}. After some algebra we obtain:

$$\begin{matrix}\frac{{J}^{*}}{J} = \frac{log ϕ ( K )}{K} ( Heisenburg ) , \\ C ( K ) = {( ϕ ( K ) )}^{3 / 4} where \\ ϕ ( K ) = \frac{{ⅇ}^{K} + 2 {ⅇ}^{- K / 2}}{3} .\end{matrix} \qquad ( 3 )$$

This is also plotted in the graph of FIG. 5. All regular three-dimensional geometries (cubic, hcp, etc.) yield kT_{c}≈0.75 zJ* for the Ising model (from high-T series expansions, see D. C. Mattis, The Theory of Magnetism, vol. II, Springer-Verlag, New York, Berlin, 1985, which is incorporated herein by reference), spins |S|=1 (where z is the coordination number of the lattice), while in the Heisenberg model for spins ½, one estimates kT_{c}≈0.5zJ*. Supposing kT_{c}=O(100K), and arbitrarily setting z=3, Eq. (3) is inverted to estimate the magnitude of the original, “physical” antiferromagnetic coupling J between nearest-neighbor spins. We find it to be J/k_{B}=T_{c}/0.6≈167K in the Heisenberg model, a small but reasonable value almost exactly what was calculated from first principles in the preceding section. Similarly, Eq. (2) can be inverted, which can be done analytically. Once the majority spins order at temperatures below T_{c}, the minority sublattice also orders but antiparallel to the majority. Thus, a net moment M that is proportional both to m₀|N_{A}−N_{B}| and to the order parameter, persists at all T<T_{c}.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An artificial ferromagnet array device, comprising:
an insulator substrate; and
a semiconductor material over the insulator substrate, the semiconductor material having a bipartite architecture comprising interconnected, nonmagnetic nanodots organized into a plurality of cells in which there is one electron per nanodot.

2. The device of claim 1, wherein the substrate comprises sapphire or quartz.

3. The device of claim 1, wherein the semiconductor material is selected from the group consisting of silicon, indium antimonide, gallium arsenide, indium phosphide, and germanium.

4. The device of claim 1, wherein the nanodots are interconnected by channels having a radius of about 1 nm to about 100 nm.

5. The device of claim 4, wherein the channels comprise carbon nanotubes.

6. The device of claim 1, wherein the nanodots are interconnected in a one-dimensional array.

7. The device of claim 1, wherein the nanodots are interconnected in a two-dimensional array.

8. The device of claim 1, wherein the nanodots are interconnected in a three-dimensional array.

9. The device of claim 1, wherein the nanodots have a spherical construction.

10. The device of claim 1, wherein the nanodots comprise branchings in channels or bulges in channels.

11. The device of claim 1, wherein the nanodots have a radius of about 1 nm to about 100 nm.

12. A nano-logical memory element, comprising:
an insulator substrate; and
a semiconductor material over the insulator substrate, the semiconductor material having a bipartite architecture comprising interconnected, nonmagnetic A and B nanodots with a given electron concentration v=1, wherein the nanodots have a permanent magnetic moment M=m₀|N_{A}−N_{B}|, where m₀ is the Bohr magneton, with N_{A} and N_{B} being the number of A and B nanodots.

13. A method for insulator-to-metallic transition that allows for signal and power amplification when a semiconductor array is imbedded in MOSFET geometry, the method comprising:
providing a semiconductor array having a bipartite architecture comprising interconnected, nonmagnetic nanodots organized into a plurality of cells in which an insulator phase exists at or near electron concentrations per nanodot of v=1, wherein a phase transition to a metallic phase occurs at or below an average electron concentration v_{c}, where v_{c} is less than 1, or when v is at or near v_{c′}, where v_{c′} is greater than 1; and
biasing a value of v near v_{c} or v_{c′} so as to increase the sensitivity of the conductivity of the semiconductor to small external changes in bias voltage.
